(19) United States
(12) Patent Application Publication
(10) Pub. No.: US 2014/0158982 A1
(43) Pub. Date: Jun. 12, 2014

(54) LIGHT-EMITTING DEVICE, BACKLIGHT UNIT, DISPLAY DEVICE, AND MANUFACTURING METHOD THEREOF

(71) Applicants: Il Woo Park, Suwon-si (KR); Hyo Jin Lee, Seoul (KR); Jeong Hee Kim, Suwon-si (KR); Na Ree Woo, Yongin-si (KR); Chang Bun Yoon, Sosa-gu Bucheon-si (KR); Chul Soo Yoon, Suwon-si (KR)

(72) Inventors: Il Woo Park, Suwon-si (KR); Hyo Jin Lee, Seoul (KR); Jeong Hee Kim, Suwon-si (KR); Na Ree Woo, Yongin-si (KR); Chang Bun Yoon, Sosa-gu Bucheon-si (KR); Chul Soo Yoon, Suwon-si (KR)

(73) Assignee: Samsung Electronics Co.,Ltd, Suwon-si (KR)

(21) Appl. No.: 14/237,036

(22) PCT Filed: Aug. 2, 2012
(86) PCT No.: PCT/KR2012/006153

§ 371 Date: Feb. 4, 2014

(30) Foreign Application Priority Data
Aug. 5, 2011 (KR) 10-2011-0078124

(51) Int. Cl. H01L 33/06; H01L 33/50

(52) U.S. Cl. CPC H01L 33/06; H01L 33/50
USPC 257/13; 438/27

(57) ABSTRACT

A light emitting device may include: a light emitting unit; a wavelength conversion unit disposed in a path of light emitted from the light emitting unit and converting a wavelength of light emitted from the light emitting unit; and a light transmission unit formed on at least one side of the wavelength conversion unit. The wavelength conversion unit may include a first quantum dot converting a wavelength of light into red light and a second quantum dot converting a wavelength of light into green light, and the patterns of first quantum dot and second quantum dot are alternately disposed repeatedly at least one or more times.

### TECHNICAL FIELD

The present disclosure relates to a light emitting device using quantum dots, a backlight unit and a display device using the same, and a manufacturing method thereof.

### BACKGROUND ART

A quantum dot is a nanocrystal made of a semiconductor material, exhibiting quantum confinement. It generates light stronger than a conventional phosphor within a narrow wavelength range.

When a quantum dot absorbs light from an excitation source to reach an energy excited state, it releases energy corresponding to a band gap thereof.

A quantum dot emits light as electrons in an excited state transition from a conduction band to a valence band, and even in the case of the same material, wavelength thereof varies according to a crystallite size thereof. A quantum dot emits light having a shorter wavelength as a size thereof becomes smaller.

Thus, an energy band gap may be adjusted by adjusting a size of a quantum dot or a material composition, whereby light having various levels of wavelength regions may be obtained.

Quantum dots are maintained in an organic solvent such that they are dispersed in a naturally coordinated form. If quantum dots are not properly dispersed or exposed to oxygen or moistures, luminous efficiency thereof is reduced.

To solve this problem, a scheme of surrounding quantum dots with an organic material has been developed. However, capping quantum dots with an organic material or a material having a greater band gap has caused issues of utility in terms of process and cost.

Thus, the development of a method that may make use of quantum dots being stable and having improved luminous performance has been required, and based on this method, an attempt to insert a quantum dot-dispersed organic solvent, polymer, or the like, into a polymer cell or a glass cell to safely protect the quantum dots from oxygen or moisture is in progress.

Meanwhile, a wavelength conversion structure using phosphors in a related art light emitting diode (LED) package involves discoloration occurring due to a reaction between a sulfuric component in using quantum dots and a silver component plated on an electrode mold, having degraded reliability.

Also, a related art backlight unit for TVs and monitors includes a diffusion layer diffusing light guided through a light guide plate, but here, examples of applying quantum dot phosphors to a diffusion layer to diffuse light have not been reported yet.

### DISCLOSURE

### Technical Problem

An aspect of the present disclosure may provide a light emitting device, a backlight unit, and a display device in which quantum dots are stably used.

An aspect of the present disclosure may also provide a light emitting device eliminating discoloration caused by a reaction between a sulfuric component and a silver component of an electrode mold.

An aspect of the present disclosure may also provide a display device available for mass production at low costs, while having improved color reproduction and thermal stability.

### Technical Solution

According to an aspect of the present disclosure, a light emitting device may include: a light emitting unit; a wavelength conversion unit disposed in a path of light emitted from the light emitting unit and converting a wavelength of light emitted from the light emitting unit; and a light transmission unit formed on at least one side of the wavelength conversion unit, wherein the wavelength conversion unit includes a first quantum dot converting a wavelength of light into red light and a second quantum dot converting a wavelength of light into green light, and the patterns of first quantum dot and second quantum dot are alternately disposed repeatedly at least one or more times. The wavelength conversion unit may be formed in an inner surface of the light transmission unit.

The light emitting unit may be comprised of at least one of white, blue, red, and green light emitting diode (LED) chips.

The wavelength conversion unit may have a light-transmissive spacer formed between patterns.

The light-transmissive spacer may include glass or a polymer resin.

The light emitting device may further include a light guide plate formed by sequentially stacking the wavelength conversion unit and the light transmission unit on an outer surface thereof.

The light transmission unit may have an inner surface and an outer surface facing the light emitting unit, and the outer surface and the inner surface may have a convex shape in an upper portion of the light emitting element.

The light emitting unit may be disposed to be surrounded by the concave inner surface of the light transmission unit.

The light emitting unit may be an incandescent lamp, the light transmission unit may be an L-tube diffusion plate, and the wavelength conversion unit may be encapsulated within the diffusion plate.

The light emitting unit may be an incandescent lamp, the light transmission unit may be an L-tube diffusion plate, and the wavelength conversion unit may be formed on an inner surface of the diffusion plate.

The light emitting device may further include a transparent encapsulator filling a space defined by the inner surface of the light transmission unit.

According to another aspect of the present disclosure, a light emitting device may include: a light emitting unit; a light transmission unit disposed in a path of light emitted from the light emitting unit and having a partition to form an accommodation space therein; a wavelength conversion unit formed in the accommodation space of the light transmission unit and including quantum dots converting a wavelength of light emitted from the light emitting unit; and a cover unit formed on the partition of the light transmission unit to cover the wavelength conversion unit.

The wavelength conversion unit may include a first quantum dot converting a wavelength of light into red light and a second quantum dot converting a wavelength of light into green light, and the patterns of first quantum dot and second quantum dot may be alternately disposed.

The wavelength conversion unit may include a first quantum dot, a second quantum dot, and a resin portion formed of a polymer resin, and the patterns of the first and second quantum dots and the resin portion may be alternately disposed.

The wavelength conversion unit may further include a quantum dot-dispersed organic solvent or a quantum dot-dispersed polymer resin.

The organic solvent may include at least one of toluene, chloroform, and ethanol.

The polymer resin may include at least one of an epoxy, silicone, polystyrene, and acrylate.

The quantum dot may include at least one nanocrystal among a silicon (Si)-based nanocrystal, a Group II-VI compound semiconductor nanocrystal, a Group III-V compound semiconductor nanocrystal, a Group IV-VI compound semiconductor nanocrystal, and any mixture thereof.

The Group II-VI compound semiconductor nanocrystal may be any one selected from the group consisting of CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HggZnTe, CdZnSeS, CdZnSeTe, CdZnSTe, CdHgSeS, CdHgSeTe, CdHgSTe, HgZnSeS, HgZnSeTe, and HgZnSTe.

The Group III-V compound semiconductor nanocrystal may be any one selected from the group consisting of GaN, GaP, GaAs, AlN, AlP, AlAs, InN, InP, InAs, GaNP, GaNAs, GaPAs, AlNP, AlNAs, AlPAs, InNP, InPAs, InPAs, GaAlNP, GaAlNAs, GaAlPAs, GaInNP, GaInNAs, GaInPAs, InAlNP, InAlNAs, and InAlPAs.

The Group IV-VI compound semiconductor nanocrystal may be SbTe.

The light emitting unit may be a light emitting diode package disposed below the light transmission unit.

Light emitted from the LED package may have a wavelength ranging from 435 nm to 470 nm, and color coordinates of red light emitted from the first quantum dot may be within an area surroundedbyfourvertices (0.5448, 0.4544), (0.7200, 0.2800), (0.6427, 0.2905), and (0.4794, 0.4633) based on the CIE 1931 color coordinates, and color coordinates of green light emitted from the second quantum dot may be within an area surrounded by four vertices of (0.1270, 0.8037), (0.4117, 0.5861), (0.4197, 0.5316), and (0.2555, 0.5030) based on the CIE 1931 color space chromaticity diagram.

Color coordinates of red light emitted from the first quantum dot may be within an area surrounded by four vertices (0.6000, 0.4000), (0.7200, 0.2800), (0.6427, 0.2905), and (0.6000, 0.4000) based on the CIE 1931 color space chromaticity diagram, and color coordinates of green light emitted from the second quantum dot may be within an area surrounded by four vertices of (0.1270, 0.8037), (0.3700, 0.6180), (0.3700, 0.5800), and (0.2500, 0.5500) based on the CIE 1931 color space chromaticity diagram.

Light emitted from the LED package may have a full-width half-maximum (FWHM) ranging from 10 nm to 30 nm, light emitted from the first quantum dot may have a FWHM ranging from 30 nm to 80 nm, and light emitted from the second quantum dot may have a FWHM ranging from 10 nm to 60 nm.

The light transmission unit may further include a lower partition formed on a lower surface thereof to accommodate the LED package.

According to another aspect of the present disclosure, a backlight unit may include the light emitting unit installed in a light guide plate in an edge manner or in a direct manner.

According to another aspect of the present disclosure, a display device may include the lighting device and an image panel displaying an image upon receiving light emitted from the light emitting device.

According to another aspect of the present disclosure, a method of manufacturing a light emitting device may include: forming a plurality of light-transmissive partitions to form one or more accommodation spaces on a base plate formed of a light-transmissive material to form a light transmission unit; filling each of the accommodation spaces with a quantum dot-dispersed solution and curing the same to form a wavelength conversion unit; forming a cover unit having a flat upper surfaces on the light transmission unit to cover the wavelength conversion unit; exposing the cover unit with ultraviolet rays (UV); dicing the light transmission unit based on each partition; and installing alight emitting diode (LED) package below the base plate of the light transmission unit.

The partitions of the light transmission unit may be formed through wet etching.

The cover unit may be formed by building a dam near left and right partitions of the light transmission unit, applying a polymer resin thereto, and planarizing the same.

The cover unit may be formed by coating a film formed of a polymer resin on an upper portion of the partition.

The light emitting device may be formed by forming a pair of left and right partitions for each LED package and dicing a gap between neighboring partitions.

The light emitting device may be formed by forming a single partition in a boundary location of each LED package, and dicing the partition into two parts.

The wavelength conversion unit may be formed in the accommodation space such that patterns of first and second quantum dots are alternately disposed.

The light transmission unit may further include a lower partition formed below the base plate to accommodate the LED package therein.

### Advantageous Effects

In the case of the light emitting device according to exemplary embodiments of the present disclosure, color reproduction characteristics and luminous efficiency may be improved by using quantum dots as a wavelength conversion member, and color coordinates may be easily adjusted by adjusting crystallite size and concentration of quantum dots.

Also, by encapsulating a quantum dot-dispersed organic solvent or polymer in a separate sealing member, an influence of oxygen or moisture thereon may be prevented, and thus, alight emitting module may be stably operated under high temperature and high moisture or high temperature atmosphere.

In addition, the use of such a light emitting device package in a backlight unit, display device, or the like, may lead to improvement of reliability and efficiency of a corresponding device.

### DESCRIPTION OF DRAWINGS

The above and other aspects, features and other advantages of the present disclosure will be more clearly understood from the following detailed description taken in conjunction with the accompanying drawings, in which:

FIG. 1 is a side-sectional view illustrating a light emitting device according to an exemplary embodiment of the present disclosure;

FIG. 2 is a side-sectional view illustrating a light emitting device according to another exemplary embodiment of the present disclosure;

FIG. 3 is a side-sectional view illustrating a light emitting device according to another exemplary embodiment of the present disclosure;

FIG. 4 is a side-sectional view illustrating a light emitting device according to another exemplary embodiment of the present disclosure;

FIG. 5 is a side-sectional view illustrating a light emitting device according to another exemplary embodiment of the present disclosure;

FIGS. 6(a) through 6(e) are side-sectional views illustrating a process of manufacturing the light emitting device of FIG. 5;

FIG. 7 is a side-sectional view illustrating another example of the light emitting device of FIG. 5;

FIG. 8 is a side-sectional view illustrating another example of the light emitting device of FIG. 5;

FIG. 9 is a side-sectional view illustrating another example of the light emitting device of FIG. 5;

FIG. 10 is a side sectional view illustrating a dicing process of another exemplary embodiment of FIG. 6;

FIG. 11 is a graph illustrating a comparison between luminous efficiency of the light emitting device according to an exemplary embodiment of the present disclosure and that of a related art light emitting device; and

FIG. 12 is a photograph illustrating a hermetic structure of a cover unit of the light emitting device of FIG. 5.

### MODE FOR INVENTION

Hereinafter, exemplary embodiments of the present disclosure will be described in detail with reference to the accompanying drawings.

The disclosure may, however, be exemplified in many different forms and should not be construed as being limited to the specific exemplary embodiments set forth herein. Rather, these exemplary embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

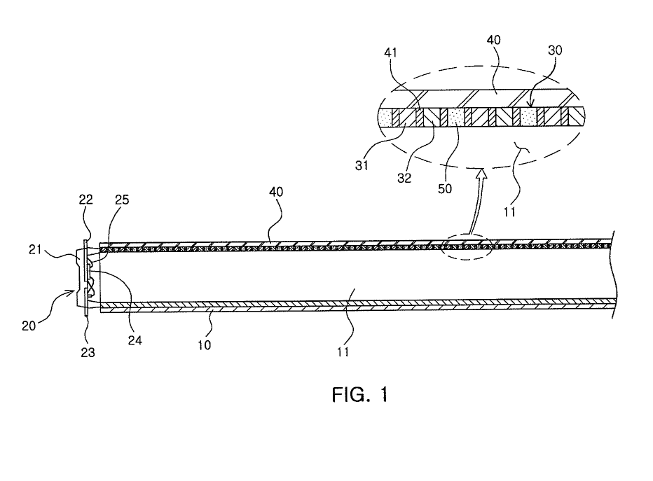

Referring to FIG. 1, a light emitting device according to the present exemplary embodiment has substantially a box shape with a light guide 11 formed therein and includes a light guide plate 10 with an open upper surface and a light emitting unit 20 installed on one side of the light guide plate 10.

A wavelength conversion unit 30 is disposed in an optical path of light emitted from the light emitting unit 20, namely, in the open upper surface of the light guide 11, and a light transmission unit 40 formed of a transparent or translucent material is disposed in an outer surface of the wavelength conversion unit 30.

The light emitting unit 20 may be configured as a light emitting element module having one or more light emitting element packages, and each light emitting element package may include a light emitting element 24, a pair of electrodes 22 and 23, a package body 21, and a wire 25.

In the present exemplary embodiment, the light emitting element 24 may be any photoelectric element as long as it emits light when an electrical signal is applied thereto, and typically, it may be a light emitting diode chip advantageous considering miniaturization and high efficiency of a light source.

Such a light emitting diode is mainly utilized as a white light emitting diode chip in a device requiring a white light source, such as a backlight unit, but it may be configured as one of red, green and blue LED chips or may be configured by combining chips having different colors, in addition to the three types, to selectively emit light having a different color.

In an example of color representation, the light emitting element 24 may be a gallium nitride (GaN)-based LED chip emitting blue light, and blue light is converted into light having a different color, for example, white light, by the wavelength conversion unit 30.

LED chips of three colors may be selectively mixed to emit white light, and all of LED chips each having a different color may be installed and different voltages may be applied to the respective chips to obtain a desired particular color.

In addition, in the present exemplary embodiment, only a single light emitting element 24 is provided, but two or more light emitting elements 24 may be provided depending on the circumstances.

The pair of electrodes 22 and 23 is electrically connected to the light emitting element 24 through conductive wires 25, and may be used as terminals for applying an external electrical signal therethrough.

To this end, the pair of electrodes 22 and 23 may be formed of a metal having excellent electrical conductivity, and one of the electrodes 22 and 23 may be provided as a mounting area of the light emitting element 24.

In the present exemplary embodiment, the light emitting element package has a structure in which the light emitting element 24 is connected to the pair of electrodes 22 and 23 through a pair of conductive wires 25 positioned in one side of the pair of electrodes 22 and 23, namely, in the right side of the drawing. However, such an electrical connection scheme is not limited thereto and may be variously modified to be applied.

For example, the light emitting element 24 may be directly electrically connected to the electrode 22 without using a wire, while being connected to the other electrode 233 through the wire 25. Also, the light emitting element 24 may be disposed according to a so-called flip-chip bonding scheme.

Here, the conductive wire 25 is illustrated as an example of a wiring structure, but it may be appropriately substituted with a different wiring structure, for example, a metal line, or the like, as long as it is able to perform an electrical signal transmission function.

The packet body 21 may serve to fix the pair of electrodes 22 and 23. A material of the package body 21 is not particularly limited and may be any material as long as it has excellent heat dissipation performance and light reflectivity, while also having electrical insulating properties

In this aspect, the package body 21 may have a structure including a transparent resin and light reflective particles (e.g., TiO₂) dispersed in the transparent resin.

The light transmission unit 40 may be formed of a material including glass or a polymer resin appropriate for protecting quantum dots from an ambient environment such as oxygen or moisture.

In the wavelength conversion unit 30, a light-transmissive spacer 41 may be disposed between patterns 31, 32, and 50. The light-transmissive spacer 41 may be formed of a material including glass or a polymer resin similar to that of the light transmission unit 40. Here, the wavelength conversion unit 30 may be manufactured as a film so as to be easily installed, and may be attached to an inner surface of the light transmission unit 40.

The wavelength conversion unit 30 includes quantum dots converting a wavelength of light emitted from the light emitting unit 20.

A quantum dot is a nanocrystal of a semiconductive material having a diameter ranging from approximately Inm to 10 nm, exhibiting a quantum confinement effect. A quantum dot converts a wavelength of light emitted from the light emitting element 24 to generate wavelength-converted light, namely, fluorescence.

Quantum dots may include, for example, a silicon (Si)-based nanocrystal, a Group II-VI compound semiconductor nanocrystal, a Group III-V compound semiconductor nanocrystal, a Group IV-VI compound semiconductor nanocrystal, and the like, and in the present exemplary embodiment, these nanocrystals may be used alone as quantum dots or a mixture thereof may be used.

As for quantum dot materials, the Group II-VI compound semiconductor nanocrystal may be any one selected from the group consisting of CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HggZnTe, CdZnSeS, CdZnSeTe, CdZnSTe, CdHgSeS, CdHgSeTe, CdHgSTe, HgZnSeS, HgZnSeTe, and HgZnSTe, for example.

The Group III-V compound semiconductor nanocrystal may be any one selected from the group consisting of GaN, GaP, GaAs, AlN, AlP, AlAs, InN, InP, InAs, GaNP, GaNAs, GaPAs, AlNP, AlNAs, AlPAs, InNP, InNAs, InPAs, GaAlNP, GaAlNAs, GaAlPAs, GaInNP, GaInNAs, GaInPAs, InAlNP, MAlNAs, and InAlPAs, for example.

The Group IV-VI compound semiconductor nanocrystal may be SbTe, for example.

Quantum dots may be dispersed in a naturally coordinated form in a dispersive medium such as an organic solvent or a polymer resin, and the dispersive medium may be any transparent medium as long as it is not transmuted by light, does not reflect light, and does not absorb light, while not affecting wavelength conversion performance of quantum dots.

For example, the organic solvent may include at least one of toluene, chloroform, and ethanol, and the polymer resin may be include at least one of epoxy, silicone, polystyrene, and acrylate.

Meanwhile, a quantum dot emits light as excited electrons transition from a conduction band to a valence band, and even in a case of the same material, wavelength thereof varies according to a crystallite size thereof.

As a size of a quantum dot becomes smaller, the quantum dot emits light having a shorter wavelength, so light having a desired wavelength region may be obtained by adjusting the size of a quantum dot. In this case, the size of a quantum dot may be adjusted by appropriately changing a growth condition of nanocrystal.

As discussed above, in the present exemplary embodiment, the light emitting element 24 may emit blue light, and in detail, the light emitting element 24 may emit light having a wavelength ranging from approximately 435 nm to 470 nm as a main wavelength.

In this case, a quantum dot converting blue light may include a first quantum dot having a peak wavelength having a size corresponding to a wavelength range of red light and converting a wavelength of light into red and a second quantum dot having a peak wavelength having a size corresponding to a wavelength range of green light and converting a wavelength of light into green.

Here, the second and first quantum dots may be appropriately adjusted in size such that the second quantum dot has a peak wavelength ranging from approximately 500 nm to 550 nm and the first quantum dot has a peak wavelength ranging from approximately 580 nm to 660 nm.

Meanwhile, a quantum dot emits intense light in a narrow wavelength range relative to a general phosphor, and thus, in the present exemplary embodiment, the second quantum dot may be set to have a full-width at half-maximum (FWHM) ranging from approximately 10 nm to 60 nm, and the first quantum dot may be set to have an FWHM ranging from approximately 30 nm to 80 nm. In this case, a blue LED chip having an FWHM ranging from approximately 10 nm to 30 nm may be employed as the light emitting element 24.

In the present exemplary embodiment, as described above, a wavelength range may be adjusted by adjusting a crystallite size of a quantum dot provided in the light emitting package, and here, the crystallite size of a quantum dot may be adjusted to have characteristics as shown in Table 1 below, for example.

TABLE 1

| | Blue | Green | Red |
|---|---|---|---|
| Wp (nm) | 455 | 535 | 630 |
| FWHM (nm) | 20 | 30 | 54 |

In Table 1, Wp is a dominant wavelength of blue light, green light, and red light, and FWHM is a half width of blue light, green light, and red light.

Referring to Table 1, blue light is light emitted from the light emitting element 24 itself, and green light and red light is light emitted from second and first quantum dots, respectively.

Also, a wavelength may be adjusted by adjusting a crystallite size of a quantum dot in use, and color coordinates may be adjusted by adjusting concentration of a quantum dot by crystallite size.

Thus, in the present exemplary embodiment, crystallite size and concentration of quantum dots may be adjusted such that color coordinates of green light emitted from the second quantum dot fall within an area surrounded by four vertices of (0.1270, 0.8037), (0.4117, 0.5861), (0.4197, 0.5316), and (0.2555, 0.5030) based on the CIE 1931 color space chromaticity diagram, and color coordinates of red light emitted from the first quantum dot fall within an area surrounded by four vertices (0.5448, 0.4544), (0.7200, 0.2800), (0.6427, 0.2905), and (0.4794, 0.4633) based on the CIE 1931 color space chromaticity diagram.

Namely, the light emitting device having the foregoing light distribution covers a very large region, exhibits a color reproduction of 95% or greater based on NTSC, and has very high light emission intensity, in comparison to a product using existing phosphors.

In addition, as mentioned above, since the quantum dots generate light stronger than that of general phosphors within a narrow wavelength range, the second and first quantum dots may be controlled to be within narrower color coordinate region.

Namely, color reproduction may be further improved by controlling color coordinates of green light emitted from the second quantum dot to fall within an area surrounded by four vertices of (0.1270, 0.8037), (0.3700, 0.6180), (0.3700, 0.5800), and (0.2500, 0.5500) based on the CIE 1931 color space chromaticity diagram, and color coordinates of red light emitted from the first quantum dot to fall within an area surrounded by four vertices (0.6000, 0.4000), (0.7200, 0.2800), (0.6427, 0.2905), and (0.6000, 0.4000) based on the CIE 1931 color space chromaticity diagram.

In this manner, in the light emitting device according to the present exemplary embodiment, color reproduction may be improved based on a combination of the light emitting element 24 and the second and first quantum dots by limiting a dominant wavelength of the light emitting element 24 and the color coordinates (based on the CIE 1931 color space chromaticity diagram) of the second and first quantum dots.

Meanwhile, in the foregoing exemplary embodiment, the case in which the light emitting element 24 is a blue LED chip and the quantum dots convert wavelength of blue light into red light and green light has been described as an example, but the present disclosure is not limited thereto.

For example, the light emitting element 24 may be an ultraviolet LED chip and quantum dots may be adjusted in crystallite size and concentration to include a blue quantum dot having a peak wavelength having a size corresponding to a wavelength range of blue light, a green quantum dot having a peak wavelength having a size corresponding to a wavelength range of green light, and a red quantum dot having a peak wavelength having a size corresponding to a wavelength range of red light.

In this case, the light emitting element 24, namely, the ultraviolet LED chip, may serve as an excitation light source of the wavelength conversion unit 30 emitting white light.

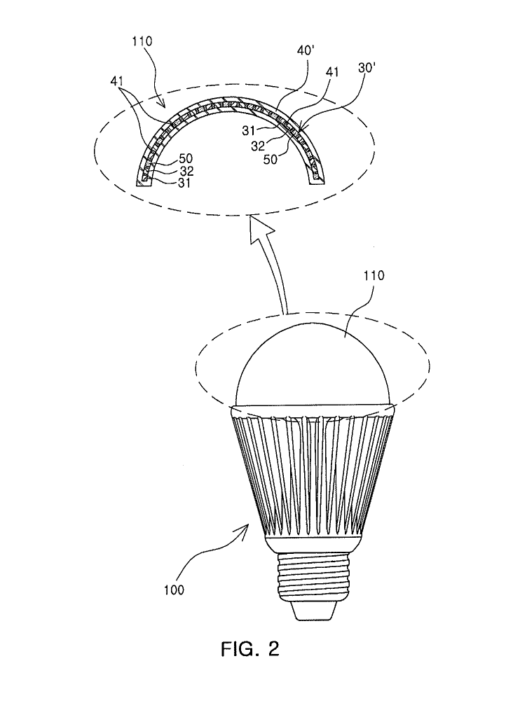

FIG. 2 is a view illustrating another exemplary embodiment in which the light emitting unit as a light emitting device is applied to an incandescent lamp 100 as a light bulb. A light transmission unit 40′ is an diffusion plate 110, disposed above a light emitting element (not shown) installed within the bulb, and, preferably, has a convex lens shape facilitating light diffusion.

In detail, the light transmission unit 40′ may be formed of a glass or a polymer resin appropriate for protecting quantum dots from an ambient environment such as oxygen and moisture and have an outer surface and an inner surface facing the light emitting element, and here, the outer surface and the inner surface of the light transmission unit 40′ may have a convex shape in an upper portion of the light emitting element.

Here, a transparent encapsulator formed of a silicone resin, or the like, may be formed in a space defined by the inner surface of the light transmission unit 40′. The transparent encapsulator may protect the light emitting device and may serve to implement refractive index matching with a material of the light emitting element. The transparent encapsulator, however, is not an essential element in the present exemplary embodiment, and may be omitted according to an exemplary embodiment of the present disclosure.

A wavelength conversion unit 30′ is encapsulated in the light transmission unit 40′ and includes quantum dots. Here, the wavelength conversion unit 30′ may include a second quantum dot 32 having a peak wavelength having a size corresponding to a wavelength range of green light and a first quantum dot 31 having a peak wavelength having a size corresponding to a wavelength range of red light.

In the wavelength conversion unit 30′, patterns including the first quantum dot 31, the second quantum dot 32, and a resin portion 50 formed of a polymer resin may be alternately and repeatedly disposed. Here, a light-transmissive spacer 41 may be disposed between the respective patterns 31, 32, and 50. The light-transmissive spacer 41 may be formed of a material including glass or a polymer resin similar to that of the light transmission unit 40′.

A quantum dot is a nanocrystal of a semiconductive material having a diameter ranging from approximately Inm to 10 nm, exhibiting a quantum confinement effect. A quantum dot converts a wavelength of light emitted from the light emitting element to generate wavelength-converted light, namely, fluorescence.

Quantum dots may include, for example, a silicon (Si)-based nanocrystal, a Group II-VI compound semiconductor nanocrystal, a Group III-V compound semiconductor nanocrystal, a Group IV-VI compound semiconductor nanocrystal, and the like, and in the present exemplary embodiment, these nanocrystals may be used alone as quantum dots or a mixture thereof may be used. Hereinafter, the foregoing descriptions will be referred to for the same parts or components as those of the former exemplary embodiment, and detailed descriptions thereof will be omitted.

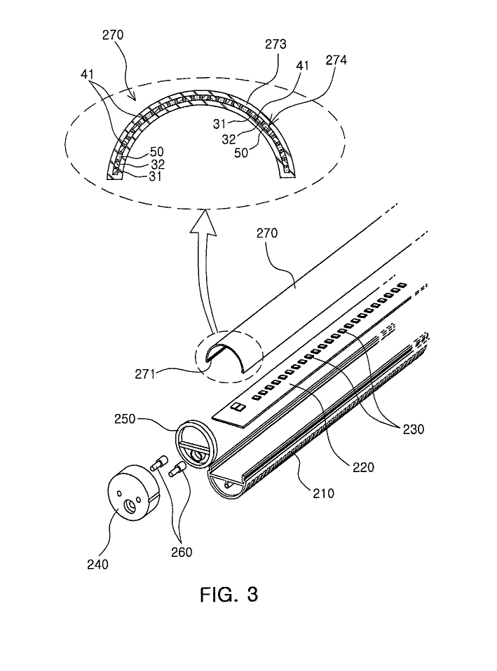

FIG. 3 is a view illustrating an example in which the light emitting device according to an exemplary embodiment of the present disclosure is applied to a flat panel lighting device, including a body 210 and a lens 270 as a light transmission unit coupled to an upper portion of the body 210. In this configuration, a plurality of light emitting elements 230 are mounted on a board 220 between the body 210 and the lens 270, and a power supply unit 240 and a fixing member 250 are disposed in one side. The body 210 and the lens 270 are coupled by a groove/protrusion structure 271, but the present disclosure is not limited thereto and the body 210 and the lens 270 may be coupled through any other methods.

A printed circuit board may be generally used as the board 220. Besides, the board 220 may be formed of an organic resin material containing an epoxy, triazine, silicone, polyimide, and the like, and any other organic resin materials, or may be formed of a ceramic material such as AlN, Al₂O₃, or the like, or a metal, a metal compound, or the like.

The light transmission unit 273 of the lens 270 constitutes an outer surface of the lens 270 and is formed of glass or a polymer resin appropriate for protecting internal quantum dots from an ambient environment such as oxygen or moisture. The light transmission unit 273 may have an outer surface and an inner surface facing the light emitting elements 230. The outer and inner surfaces of the light transmission unit 273 may have a convex shape above the light emitting elements 230.

A wavelength conversion unit 274 is encapsulated in the light transmission unit 273 and includes quantum dots. Here, the wavelength conversion unit 274 may include a second quantum dot 32 having a peak wavelength having a size corresponding to a wavelength range of green light and a first quantum dot 31 having a peak wavelength having a size corresponding to a wavelength range of red light.

In the wavelength conversion unit 274, patterns including the first quantum dot 31, the second quantum dot 32, and a resin portion 50 formed of a polymer resin may be alternately and repeatedly disposed. Here, a light-transmissive spacer 41 may be disposed between the respective patterns 31, 32, and 50. The light-transmissive spacer 41 may be formed of a material including glass or a polymer resin similar to that of the light transmission unit 273.

In the present exemplary embodiment, since the wavelength conversion unit 274 having hermetically sealed quantum dots are provided on the individual light emitting elements 230, the use of a board with a plurality of light emitting elements 230 mounted thereon may obtain a high degree of reliability.

Also, since the wavelength conversion unit 274 and the light transmission unit 273 are provided in the form of the lens 270 diversifying velocity of light and radiation patterns of the light emitting elements 230, an angle of beam spread may be appropriately adjusted, enhancing luminous characteristics.

Hereinafter, the foregoing descriptions will be referred to for the same parts or components as those of the former exemplary embodiment, and detailed descriptions thereof will be omitted.

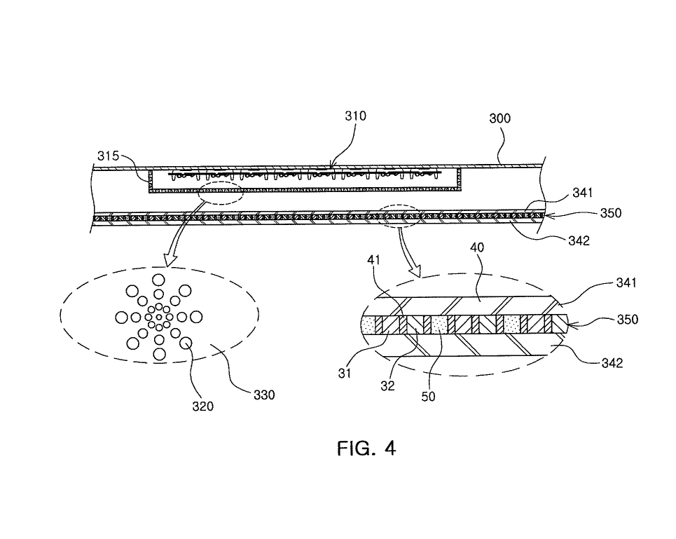

FIG. 4 is a view illustrating a structure of a ceiling lamp according to another exemplary embodiment of the present disclosure, in which a plurality of light emitting elements are attached to a lower surface of a reflective plate 300 by using a carrier sheet 310. In detail, a light transmission units 341 and 342 having a dual-plate structure and including glass or a polymer resin are disposed in a lower side, and a wavelength conversion unit 350 is formed therebetween.

Here, a light adjusting cover 315 may be installed below the carrier sheet 310. The light adjusting cover 315 has a plurality of light transmission holes. As for a light emitting element, a central portion thereof has a quantity of light greater than that of a peripheral portion thereof. Thus, the light transmission holes of the light adjusting cover 315 may be configured to have diameters gradually increased toward the peripheral portion from the center thereof.

Namely, referring to FIG. 4, in the light adjusting cover 315, light transmission holes 330 each having a smaller diameter may be formed in a portion corresponding to the central portion of the light emitting element, and light transmission holes 320 each having a larger diameter may be formed in a portion corresponding to the peripheral portion of the light emitting element. The light transmission holes having these patterns may be continuously formed to correspond to the light emitting elements on the light adjusting cover 315.

The wavelength conversion unit 350 is encapsulated between the upper plate 341 and the lower plate 342 and includes quantum dots including a second quantum dot 32 having a peak wavelength having a size corresponding to a wavelength range of green light and a first quantum dot 31 having a peak wavelength having a size corresponding to a wavelength range of red light. Here, the wavelength conversion unit 274 may be manufactured as a patterned film and attached between the upper plate 341 and the lower plate 342.

In the wavelength conversion unit 350, patterns including the first quantum dot 31, the second quantum dot 32, and a resin portion 50 formed of a polymer resin may be alternately and repeatedly disposed. Here, a light-transmissive spacer 41 may be disposed between the respective patterns 31, 32, and 50. The light-transmissive spacer 41 may be formed of a material including glass or a polymer resin similar to that of the light transmission units 341 and 342. Here, the above description will be referred to for the same parts as those of the former exemplary embodiment, and descriptions thereof will be omitted.

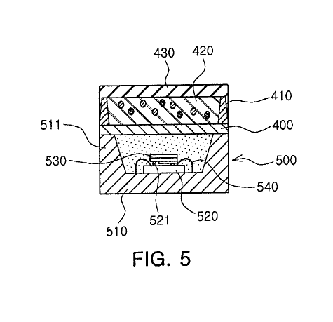

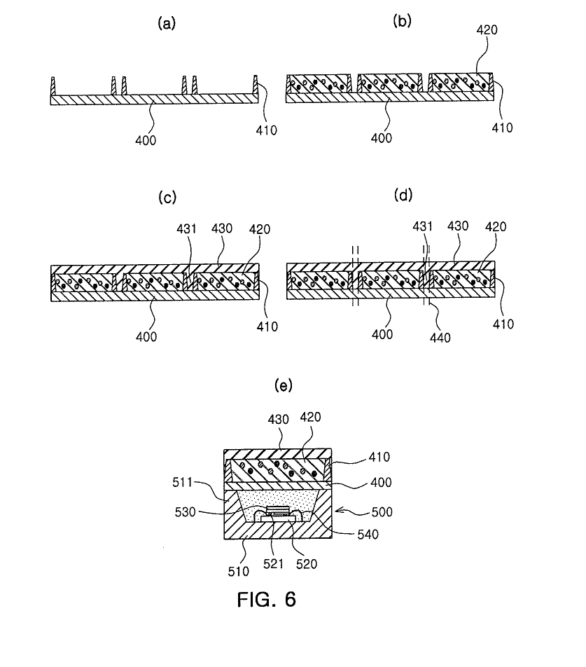

FIGS. 5 and 6 illustrate a light emitting device according to another exemplary embodiment of the present disclosure. Referring to FIGS. 5 and 6, the light emitting device according to the present exemplary embodiment includes a light emitting unit 500 and a light transmission unit 400 formed above the light emitting unit 500 and having a partition 410 providing an accommodation space formed therein. The light transmission unit 400 may include a wavelength conversion unit 420 formed in the accommodation space of the light transmission unit 410, and a cover unit 430 formed of thiol and formed on the partition 410 to cover the wavelength conversion unit 420 in order to prevent the wavelength conversion unit 420 from being exposed to moisture or oxygen.

The light emitting unit 500 may include a light emitting element 520, a pair of electrodes 530, a package body 510 having a recess portion, and wires 540.

The light transmission unit 400 and the partition 410 may be formed of a material including glass or a polymer resin appropriate for protecting quantum dots from an ambient environment such as oxygen or moisture.

The wavelength conversion unit 420 includes quantum dots for converting a wavelength of light emitted from the light emitting unit 500. The quantum dots may be dispersed in a naturally coordinated form in a dispersive medium such as an organic solvent or a polymer resin, and the dispersive medium may be any transparent medium as long as it is not transmuted by light, does not reflect light, and does not absorb light, while not affecting wavelength conversion performance of quantum dots.

For example, the organic solvent may include at least one of toluene, chloroform, and ethanol, and the polymer resin may be include at least one of epoxy, silicone, polystyrene, and acrylate.

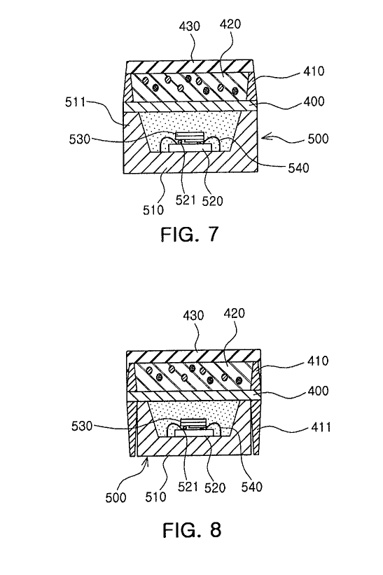

The cover unit 430 may be formed to cover an outer surface of the partition 410 by a predetermined thickness in order to provide a protection effect to the partition 410, and here, as illustrated in FIG. 7, the cover 430 may not be formed on an outer surface of the partition 410.

As illustrated in FIG. 8, a lower partition 411 may be formed on a lower surface of the light transmission unit 400 to accommodate an outer surface of the package body 410 of the light emitting unit 500 in order to stabilize a combined state of the light emitting unit 500.

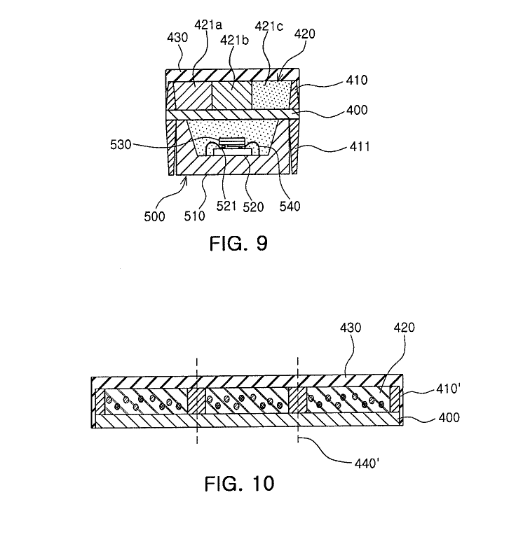

Meanwhile, as illustrated in FIG. 9, the wavelength conversion unit 420 is encapsulated in the accommodation space of the light transmission unit 400 and includes quantum dots. Here, the wavelength conversion unit 420 may include a second quantum dot 421a having a peak wavelength having a size corresponding to a wavelength range of green light and a first quantum dot 421b having a peak wavelength having a size corresponding to a wavelength range of red light.

In the wavelength conversion unit 420, patterns including the first quantum dot 421b, the second quantum dot 421a, and a resin portion 421c formed of a polymer resin may be alternately and repeatedly disposed.

A method for manufacturing the light emitting device having the aforementioned configuration according to an exemplary embodiment of the present disclosure will be described as follows.

First, a light emitting unit is manufactured by forming a plurality of light-transmissive partitions 410 on a base plate 400 formed of a light-transmissive material such that the light-transmissive partitions 410 are spaced apart from one another to form one or more accommodation spaces therebetween. Here, the partitions may be formed by using wet etching, but the present disclosure is not limited thereto and the partitions may be formed through any other method. Also, if needed, the lower partition 411 may be formed in a lower portion of the base plate through a method such as the wet etching identical as mentioned above, or the like, to accommodate a light emitting element package.

The respective accommodation spaces are filled with a quantum dot dispersed solution and cured to form the wavelength conversion unit 420. Here, first and second quantum dot patterns formed of a red quantum dot material and a green quantum dot material may be alternately disposed in the accommodation spaces. Namely, in a case in which a light emitting element is configured as a blue LED chip, this structure is provided to emit white light.

Thereafter, a dam is built near the left and right partitions 410 of the light transmission unit 400, a polymer resin is applied to an upper portion of the light transmission unit 400 to cover each wavelength conversion unit, and planarized through a planarization unit such as a scraper, to form the cover unit 430 having a flat upper surface; here, gaps 431 between the respective partitions 410 are filled with a polymer resin.

On the other hand, the cover unit 430 may be formed by manufacturing a film with a polymer resin and coating the film on upper portions of the partitions 410 to cover the wavelength conversion unit 420.

Thereafter, the cover unit 430 is exposed to ultraviolet rays (UV), and the light transmission unit 400 is diced based on gaps 431 between partitions 410.

In comparison with the related art in which the cover unit 430 is formed in a simple coating method to have an upwardly convex dome shape, the cover unit 430 has a flat upper surface.

Thereafter, the LED package 500 is attached to a lower portion of the base plate of the light transmission unit 400 in order to complete a light emitting device.

On the other hand, as illustrated in FIG. 10, a single partition 410′ may be installed in a boundary position of each LED package and cut into two parts along a cutting line 440′ in a dicing process, in order to simplify the process while reducing manufacturing costs.

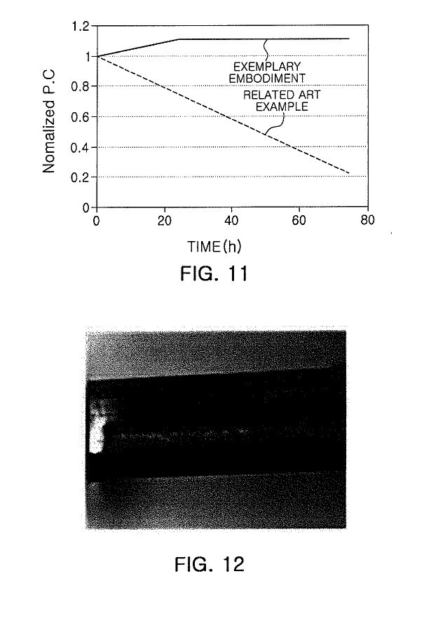

FIG. 11 is a graph illustrating a comparison between the light emitting device according to the present exemplary embodiment and the related art light emitting device having a dome-shaped cover unit.

In FIG. 11, it may be seen that the light emitting device according to the present exemplary embodiment having the cover unit with a flat upper surface has luminous efficiency slowly deteriorated over time under conditions in which a temperature is 85° C. and humidity is 85%, relative to the related art.

This may also be seen in an SEM and optical microscope photograph of FIG. 12. Referring to the photograph of FIG. 12, an attachment structure of the cover unit 430 is an airtight structure.

Meanwhile, the light emitting device configured as described above may further include a light guide plate so as to be used as a backlight unit used in a display device such as a liquid crystal display (LCD) having an image panel, indoor lighting such as a lamp, flat panel lighting, or outdoor lighting device such as a streetlight, a signboard, a sign, or the like. The foregoing backlight unit may be classified as an edge-type backlight unit and a direct-type backlight unit according to a way in which a light emitting unit is installed, but the present disclosure is not limited thereto.

Also, the light emitting deice may be used in various lighting devices for means of transportation, for example, vehicles, ships, airplanes, and the like, and may further be widely used in home appliances such as TVs, refrigerators, or the like, medical appliances, and the like.

While exemplary embodiments have been shown and described above, it will be apparent to those skilled in the art that modifications and variations could be made without departing from the spirit and scope of the present disclosure as defined by the appended claims.

1. A light emitting device, comprising:
a light emitting unit;
a wavelength conversion unit disposed in a path of light emitted from the light emitting unit and converting a wavelength of light emitted from the light emitting unit; and
a light transmission unit disposed on at least one side of the wavelength conversion unit,
wherein the wavelength conversion unit includes a first quantum dot converting a wavelength of light into red light and a second quantum dot converting a wavelength of light into green light, and
patterns of the first quantum dot and the second quantum dot are alternately disposed repeatedly at least one or more times.

2. The light emitting device of claim 1, wherein the wavelength conversion unit comprises a first quantum dot, a second quantum dot, and a resin portion, and patterns of the first quantum dot, the second quantum dot, and the resin portion are alternately disposed repeatedly at least one or more times.

3. (canceled)

4. (canceled)

5. (canceled)

6. The light emitting device of claim 1, wherein the wavelength conversion unit is disposed on an inner surface of the light transmission unit.

7. The light emitting device of claim 6, wherein the wavelength conversion unit has a film shape.

8-16. (canceled)

17. The light emitting device of claim 1, wherein the wavelength conversion unit has a light-transmissive spacer formed between patterns.

18. The light emitting device of claim 17, wherein the light-transmissive spacer includes glass or a polymer resin.

19. The light emitting device of claim 1, further comprising a light guide plate formed by sequentially stacking the wavelength conversion unit and the light transmission unit on an outer surface thereof.

20. The light emitting device of claim 1, wherein the light transmission unit has an inner surface and an outer surface facing the light emitting unit, and the outer surface and the inner surface have a convex shape in an upper portion of the light emitting element.

21. The light emitting device of claim 20, wherein the light emitting unit is disposed to be covered by the convex inner surface of the light transmission unit.

22-24. (canceled)

25. A light emitting device, comprising:
a light emitting unit;
a light transmission unit disposed in a path of light emitted from the light emitting unit and having a partition to form an accommodation space therein;
a wavelength conversion unit disposed in the accommodation space of the light transmission unit and including quantum dots converting a wavelength of light emitted from the light emitting unit; and
a cover unit formed on the partition of the light transmission unit to cover the wavelength conversion unit.

26. The light emitting device of claim 25, wherein the wavelength conversion unit includes a first quantum dot converting a wavelength of light into red light and a second quantum dot converting a wavelength of light into green light, and the patterns of first quantum dot and second quantum dot are alternately disposed.

27. The light emitting device of claim 25, wherein the wavelength conversion unit comprises a first quantum dot, a second quantum dot, and a resin portion, and the patterns of the first quantum dot, the second quantum dot, and the resin portion are alternately disposed.

28-34. (canceled)

35. The light emitting device of claim 26, wherein the light emitting unit is disposed below the light transmission unit.

36-38. (canceled)

39. The light emitting device of claim 35, wherein the light transmission unit further comprises a lower partition formed on a lower surface thereof to accommodate the LED package therein.

40. (canceled)

41. The light emitting device of claim 25, wherein the cover unit includes thiol.

42-45. (canceled)

46. A method of manufacturing a light emitting device, the method comprising:
forming a plurality of light-transmissive partitions to form one or more accommodation spaces on a base plate formed of a light-transmissive material to form a light transmission unit;
filling each of the accommodation spaces with a quantum dot-dispersed solution and curing the same to form a wavelength conversion unit;
forming a cover unit having a flat upper surfaces on the light transmission unit to cover the wavelength conversion unit;
exposing the cover unit with ultraviolet rays (UV);
dicing the light transmission unit based on each partition; and
installing a light emitting diode (LED) package below the base plate of the light transmission unit.

47. (canceled)

48. The method of claim 46, wherein the cover unit is formed by building a dam near left and right partitions of the light transmission unit, applying a polymer resin thereto, and planarizing the same.

49. The method of claim 46, wherein the cover unit is formed by coating a film formed of a polymer resin on an upper portion of the partition.

50. The method of claim 46, wherein the light emitting device is formed by forming a pair of left and right partitions for each LED package and dicing a gap between neighboring partitions.

51. The method of claim 46, wherein the light emitting device is formed by forming a single partition in a boundary location of each LED package, and dicing the partition into two parts.

52. (canceled)

53. (canceled)
